(19) United States
(12) Patent Application Publication
(10) Pub. No.: US 2024/0321999 A1
(43) Pub. Date: Sep. 26, 2024

(54) FERROELECTRIC FIELD MODULATED POSITIVE AND NEGATIVE PHOTO-RESPONSE DETECTOR, PREPARATION METHOD AND APPLICATION THEREOF

(71) Applicant: Fudan University, Shanghai (CN)

(72) Inventors: Jianlu WANG, Shanghai (CN); Guangjian WU, Shanghai (CN)

(73) Assignee: Fudan University, Shanghai (CN)

(21) Appl. No.: 18/024,277

(22) PCT Filed: Jul. 8, 2022
(86) PCT No.: PCT/CN2022/104580

§ 371 Date: Mar. 2, 2023

(30) Foreign Application Priority Data
May 31, 2022 (CN) 202210612923.7

(51) Int. Cl. H01L 29/51; G06N 3/06; H01L 31/113; H01L 31/18

(52) U.S. Cl. CPC H01L 29/516; G06N 3/06; H01L 31/1136; H01L 31/18

(57) ABSTRACT

The present invention relates to a photo-response detector, in particular to a ferroelectric field modulated positive and negative photo-response detector, a preparation method and application thereof. The ferroelectric field modulated positive and negative photo-response detector includes a substrate, a gate electrode, a ferroelectric layer, a low-dimensional semiconductor and a source-drain electrode. A pair of gate electrodes are provided and fixedly arranged on the substrate at intervals. The ferroelectric layer is fixedly arranged on the substrate and completely covers the gate electrode. The low-dimensional semiconductor is fixedly arranged on the ferroelectric layer. The source-drain electrode includes a source electrode and a drain electrode separately arranged on two sides of the low-dimensional semiconductor and fixedly arranged on the ferroelectric layer.

### FIELD OF TECHNOLOGY

The present invention relates to a photo-response detector, in particular to a ferroelectric field modulated positive and negative photo-response detector, a preparation method and application thereof.

### BACKGROUND

With the powerful intelligent vision system, human beings can clearly and effectively detect and process the surrounding environment information synchronously with low energy consumption. Therefore, building an efficient intelligent vision system based on novel devices is the goal that human beings dream of. Although people have made great efforts to simulate the visual cortex of human brain to realize the function of “seeing”, the physically separated sensing, memory and processing units in traditional visual processing systems lead to a lot of energy consumption, time delay and extra hardware cost. Especially with the rapid development of the Internet of Things and the increasing demand for image resolution, visual information has exploded. Bandwidth limitation will further limit the transmission efficiency of information between sensing and computing cores, which is an urgent challenge to be solved in the application fields that need real-time processing and decision-making, such as intelligent industry, automatic driving and intelligent security.

In order to simulate the efficient information process of the brain, the current artificial sensors still need to further integrate intelligent sensing ability, so as to achieve brain-like intelligent vision with fusion of sense and memory. This requires that the terminal sensor should have many bionic functions of human retina at the same time. The cells in human retina are mainly photoreceptor cells and bipolar cells. Photoreceptor cells convert the incident light into electric signals, which flow through bipolar cells. After preprocessing the electrical information through the biological characteristics of bipolar cells, the image information only retains its main features, and then transmits to the cerebral cortex for further image processing and understanding. Owning to advanced processing technology and multi-field regulation effect of energy band structure, it is reported that many photoelectric devices can simulate the bionic function of photoelectric conversion of photoreceptor cells, can also simulate the subsequent synaptic weight adjustment at the same time, and achieve image processing integrating sensing, storage and computing. However, although it plays an extremely important role in improving efficiency and handling dynamic related tasks, the function of bipolar cells in retina is rarely realized in bionic devices. This is because bipolar cells divert the electric signals transmitted by photoreceptors into on and off signals through different glutamate receptors on their dendrites. The on and off signals correspond to the positive and negative photoelectric responses in the bionic vision device, but it is challenging to realize the programmable positive and negative photoelectric signals in the same photoelectric device at the same time.

The Patent CN112542515A discloses a photoelectric regulated neural synaptic transistor, where the transistor includes a substrate, a back gate electrode, a ferroelectric film, a channel layer and a light anti-reflection layers from bottom to top, wherein a source electrode and a drain electrode are arranged at the two ends of the light anti-reflection layer respectively, the channel layer is made of one or more layers of low-dimensional materials, and at least one layer of low-dimensional materials makes contact with the source electrode and the drain electrode. The ferroelectric film has a ferroelectric polarization effect, and the ferroelectric domain reversal characteristics is regulated and controlled by the back gate electrode. In terms of function, the patent only discloses a neural synaptic device, which is responsible for changing the strength of the connection of anterior and posterior neurons. In terms of device performance, the device shown in this patent only has positive device response. To sum up, the device proposed in this patent cannot meet the simulation of bipolar cells.

### SUMMARY

The present invention aims at solving at least one of the above problems and provides a ferroelectric field modulated positive and negative photo-response detector, a preparation method and an application thereof, and achieves the simultaneous realization of programmable positive photoelectric signals and negative photoelectric signals in the same photoelectric device.

The purpose of the present invention is realized by the following technical solution. The first aspect of the present invention discloses a ferroelectric modulated positive and negative photo-response detector consisting of a substrate, a gate electrode, a ferroelectric layer, a low-dimensional semiconductor and a source-drain electrode;

a pair of gate electrodes are provided and fixedly arranged on the substrate at intervals;

the ferroelectric layer is fixedly arranged on the substrate and completely covers the gate electrode;

the low-dimensional semiconductor is fixedly arranged on the ferroelectric layer; and

the source-drain electrode includes a source electrode and a drain electrode separately arranged on two sides of the low-dimensional semiconductor and fixedly arranged on the ferroelectric layer.

Preferably, the substrate is an insulating substrate.

Preferably, the substrate is a Si/SiO₂ or sapphire substrate.

Preferably, the gate electrode is a Cr/Au bottom gate electrode with a thickness of 10 nm/10 nm, and a distance between the two gate electrodes is 1 μm.

Preferably, the ferroelectric layer contains a P (VDF-TrFE) ferroelectric material. The thickness of the ferroelectric layer only needs to maintain its ferroelectricity, for example, the thickness of the ferroelectric layer can be set to 300 nm. Preferably, the low-dimensional semiconductor is aligned with the gate electrode.

Preferably, the low-dimensional semiconductor is a bipolar two-dimensional or one-dimensional semiconductor, such as WSe₂, MoTe₂.

Preferably, the source-drain electrode is a Cr/Au source-drain electrode with a thickness of 15 nm/45 nm and a channel width of 10 μm.

The second aspect of the present invention discloses a method for preparing the ferroelectric field-modulated positive and negative photo-response detector as described above, which includes:
preparing a pair of gate electrodes at intervals on a substrate by a photolithography process, and preparing a ferroelectric layer on the substrate by spin coating and annealing process; preparing a low-dimensional semiconductor on the ferroelectric layer by a semiconductor transfer technique, then preparing an electrode pattern by an ultraviolet lithography method, preparing a source-drain electrode by a thermal evaporation technique, and peeling off a metal film by a lift-off method to obtain the positive and negative photo-response detector.

Preferably, the annealing is performed at 135° C. for 2 hours.

The third aspect of the present invention discloses an application of the ferroelectric field modulated positive and negative photo-response detector as described above in an intelligent vision system.

Preferably, the positive and negative photo-response detector serves in an intelligent vision system as photoreceptor cells, bipolar cells and synapses connected to cerebral cortex of retina of human eyes.

In this solution, based on a structure of the split gate device, a high-speed and high-sensitivity PN-junction and NP-junction photodetector is constructed by regulating low dimension semiconductors with a ferroelectric field, in which negative photocurrent is generated under the illumination of PN junction, and positive photocurrent is generated under the illumination of NP junction. The photocurrent is continuously and linearly adjustable from positive to negative by applying pulse voltage to the split gate electrode, and the programmable positive photoelectric signal and negative photoelectric signal are realized simultaneously in the same photoelectric device.

A working principle of the present invention is:
the device does not respond to light when the ferroelectric layer is not polarized. Ferroelectric materials can be polarized by applying pulse voltage to gate electrodes. When positive/negative (negative/positive) pulse voltage is applied to left/right gate electrodes respectively, the polarized materials are polarized up/down (down/up), and the corresponding device state is NP (PN) junction. Further increasing the ferroelectric field can strengthen the photo-response.

The continuous regulation of PN and NP junction is implemented by applying pulsed voltage, and the regulation is performed in an order: voltage pulse→ferroelectric field→PN junction band structure→device photocurrent. That is to say, polarities (positive and negative) of the device photocurrent can be continuously adjusted under the same illumination condition by applying pulse voltage to the gate electrode.

Compared with the prior art, the present invention has the following beneficial effects:
(1) The photodetector based on PN built-in electric field has the characteristics of high speed and high sensitivity, which can play an important role in improving efficiency and processing dynamic related tasks, and provide a basis for realizing the intelligent vision system integrating sensing, storage and computing.
(2) Under the modulation of pulse voltage, the photocurrent of the device can be continuously and linearly adjusted from positive to negative, and the process is stable for multiple cycles, so that it can achieve programmable positive photoelectric signal and negative photoelectric signal simultaneously in the intelligent vision system.
(3) The device responds linearly to the incident light with different intensity, which provides the precondition for gray image processing.
(4) When the device works, it needs neither bias voltage nor gate voltage, and implements self-driven photoresponse.
(5) After forming an array, the device can integrate image sensing, weight storage and computing, and can cover the functions of synapses and neurons. Furthermore, the device also presents positive and negative photo-response (weight value), which is of great significance for the realization of bionic artificial visual neural system.

### BRIEF DESCRIPTION OF THE DRAWINGS

FIG. 1 is a schematic diagram of a preparation process of a photo-response detector according to Embodiment 1;

FIG. 2 is a schematic diagram of a working principle of the photo-response detector according to Embodiment 1;

FIG. 3(a) shows a change of device photocurrent under voltage pulse modulation; FIG. 3(b) shows a change of device photocurrent under multiple cycles;

FIG. 4 is a diagram showing a change of current of the detector with time under the same illumination condition and different polarization states of the detector according to Embodiment 1;

FIG. 5 is a diagram showing a response relationship between photocurrent and optical power in different polarization states of the detector according to Embodiment 1; and

FIG. 6 is a schematic diagram of a conversion principle of positive and negative light responses of the detector according to the present invention.

In the drawings: 1-substrate; 2-gate electrode; 3-ferroelectric layer; 4-low-dimensional semiconductor; 5-source-drain electrode; 51-source electrode; 52-drain electrode.

### DESCRIPTION OF THE EMBODIMENTS

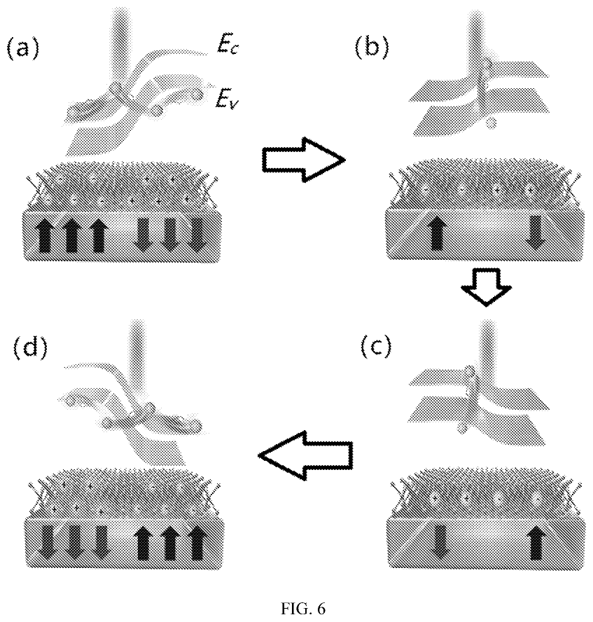

The core of the present invention is to achieve the continuous adjustment of PN junction energy band and NP junction energy band by using ferroelectric field, where NP junction can produce negative photocurrent under illumination, while PN junction can produce positive photocurrent under illumination, and the gradual transition between them forms a continuously adjustable photocurrent from negative to positive, while the regulation of energy band of semiconductor PN junction and NP junction depends on ferroelectric field. As shown in FIG. 6, and referring to the structure of FIG. 2, from top to bottom are the low-dimensional semiconductor 4 material band diagram, the low-dimensional semiconductor 4, and the ferroelectric material, where arrows in the ferroelectric material indicate their polarization directions. As you can see, when the ferroelectric material on the left side (that is, the ferroelectric material above the gate 1 refer to the position of the gate 1 in FIG. 2) is polarized upward, its ferroelectric field will form N-type doping in the low-dimensional semiconductor 4 material, and when the ferroelectric material on the right side (i.e., the ferroelectric material above the gate 2, refer to the position of the gate 2 in FIG. 2) is polarized downward, its ferroelectric field will form P-type doping in the low-dimensional semiconductor 4 material, thus constructing the NP junction. At this time, a pulse voltage is applied to the gate 1 and gate 2, so that the polarized domains on both sides are partially reversed, so that the ferroelectric fields on both sides are weakened, which leads to the weakening of N-type doping in the left semiconductor and the weakening of P-type doping in the right semiconductor, and an NP junction with a built-in electric field smaller than 1 is formed, as shown in FIG. 6(b). The ferroelectric layer 3 is further turned over by applying pulsed voltages to the gates 1 and 2, and the ferroelectric polarization on the left is downward and the ferroelectric polarization on the right is upward, so that the low-dimensional semiconductor 4 forms a weak PN junction, as shown in FIG. 6(c). Continuing to apply the pulse voltage over the gate 1 and gate 2, the reverse polarization electric field becomes stronger, forming a PN junction with the same magnitude and opposite direction as the built-in electric field in FIG. 6(a), as shown in FIG. 6(d). The regulation relationship is voltage pulse→ferroelectric domain→built-in electric field of PN junction→device. It should be noted that FIG. 6 shows only part of the node state in the transformation process, but not a complete change process, and the actual change is continuous change. In addition, FIG. 6 shows the change process from NP junction to PN junction, and the change process from PN junction to NP junction is consistent with that shown in FIG. 6, except that the polarization direction is opposite.

The method for preparing the ferroelectric field-modulated positive and negative photo-response detector as described above includes: preparing a pair of gate electrodes 2 at intervals on a substrate 1 by a photolithography process, and preparing a ferroelectric layer 3 on the substrate 1 by a spin coating and annealing; and preparing a low-dimensional semiconductor 4 on the ferroelectric layer 3 by a semiconductor transfer technique, then preparing an electrode pattern by an ultraviolet lithography method, preparing a source-drain electrode 5 by a thermal evaporation technique, and peeling off a metal film by a lift-off method to obtain the positive and negative photo-response detector.

The annealing is performed at 135° C. for 2 hours.

The ferroelectric field modulated positive and negative photo-response detector is applied in an intelligent vision system.

Preferably, the positive and negative photo-response detector serves in an intelligent vision system as photoreceptor cells, bipolar cells and synapses connected to cerebral cortex of retina of human eyes.

### Embodiment 1

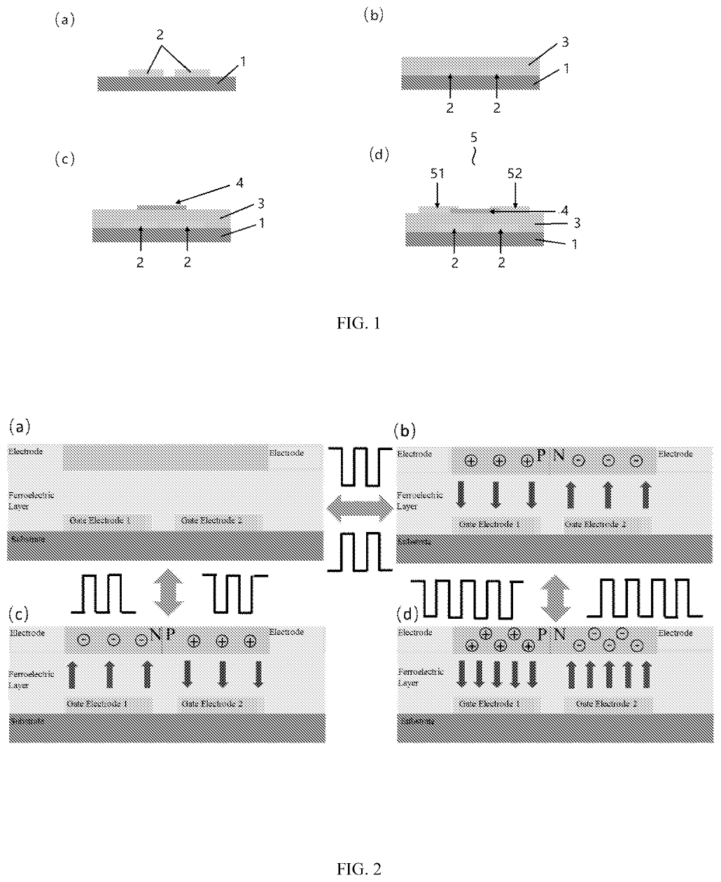

A ferroelectric field modulated positive and negative photo-response detector, as shown in FIGS. 1-5, consists of a substrate 1, a gate electrode 2, a ferroelectric layer 3, a low-dimensional semiconductor 4 and a source-drain electrode 5).

A pair of gate electrodes 2 are provided and fixedly arranged on the substrate 1 at intervals.

The ferroelectric layer 3 is fixedly arranged on the substrate 1 and completely covers the gate electrode 2.

The low-dimensional semiconductor 4 is fixedly arranged on the ferroelectric layer 3.

The source-drain electrode 5 comprises a source electrode 51 and a drain electrode 52 separately arranged on two sides of the low-dimensional semiconductor 4 and fixedly arranged on the ferroelectric layer 3.

As shown in FIG. 1, the detector of this embodiment is prepared by the following steps:
Step (1): a pair of Cr/Au bottom gate electrodes 2 is prepared by photolithography on an insulating substrate 1 (such as Si/SiO₂ or sapphire substrate, in this embodiment, the sapphire substrate is adopted), as shown in FIG. 1(a), the thickness of the Cr/Au electrodes is 10 nm/10 nm and an interval between the two electrodes is 1 m.
Step (2): A ferroelectric functional layer is prepared. A P(VDF-TrFE) ferroelectric functional layer was prepared on substrate 1 by spin coating method, as shown in FIG. 1 (b), and annealed at 135° C. for 2 hours to ensure its crystallization characteristics. The ferroelectric layer 3 in this embodiment is set to 300 nm.
Step (3): A bipolar two-dimensional semiconductor layer (low-dimensional semiconductor layer 4, specifically WSe₂ or MoTe₂, and WSe₂ can be selected in this embodiment) is prepared on the ferroelectric layer 3 by semiconductor transfer technology, so that its position is aligned with the bottom electrode for easy regulation, as shown in FIG. 1(c).
Step (4): a Cr/Au source drain electrode 5 is prepared. An electrode pattern was prepared by ultraviolet lithography. Metal electrodes were prepared by thermal evaporation technology, with chromium 15 nm and gold 45 nm. Combined with lift-off method, the metal film was peeled off to obtain a metal electrode with a channel width of 10 μm, as shown in FIG. 1(d).

The working principle of the detector in this embodiment is that the device does not respond to light when the ferroelectric layer is not polarized (FIG. 2(a)). Ferroelectric materials (FIG. 2(a) and FIG. 2(b)) can be polarized by applying pulse voltage to gate electrodes 2. When positive/negative (negative/positive) pulse voltage is applied to left/right gate electrodes 2 respectively, the polarized materials are polarized up/down (down/up), and the corresponding device state is NP (PN) junction, which further increases the ferroelectric field strengthens the response FIG. 2(d). The continuous regulation of PN and NP junction can be implemented by changing the polarity of the pulsed voltage, and the regulation is performed in an order: voltage pulse→ferroelectric field→PN junction band structure→device photocurrent. That is to say, polarities (positive and negative) of the photocurrent of the device can be continuously adjusted under the same illumination condition by applying pulse voltage to the gate electrode.

Polarities (positive and negative) of the photocurrent of the detector are linearly adjustable under pulse voltage modulation.

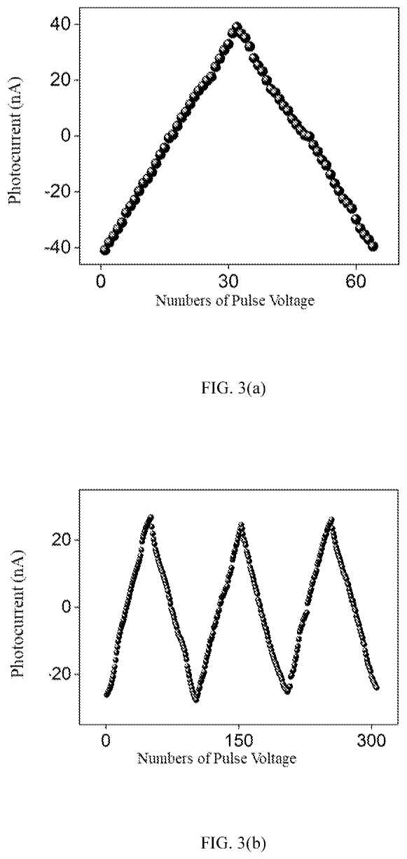

As shown in FIG. 3(a), under the same illumination condition, the polarities (positive and negative) of the photocurrent of the detector can be linearly adjusted by applying a reverse pulse voltage to two gate electrodes 2. When the pulse voltage at the left/right gate changes from −16 to −21V/+16 to +21V, with a step of −0.1 V/0.1 V, a pulse width of 1 ms, the photocurrent changes from negative to positive. The polarity of the pulse voltage is opposite when the photocurrent changes from positive to negative. In addition, as can be seen from FIG. 3(b), the detector is available for multiple cycles, which shows that the device has good stability.

### Retention Characteristics of Detector:

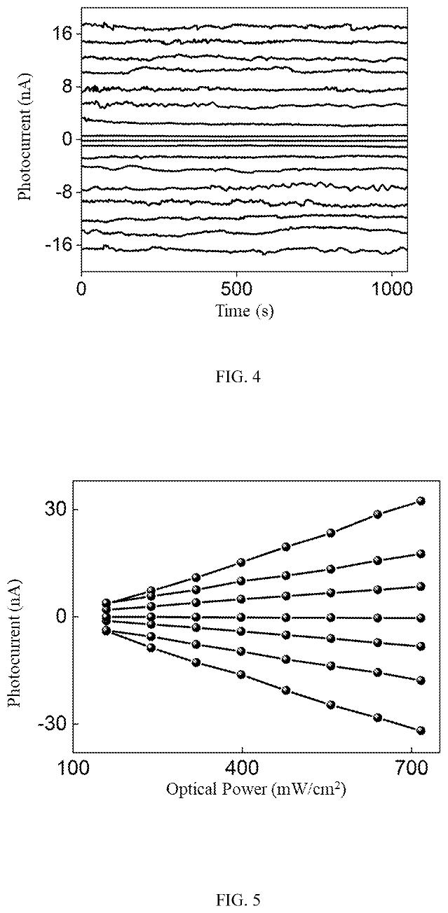

the retention characteristics of the detector are also very important for the operation of the detector. FIG. 4 shows the change of the current of the device with time under the same illumination condition and different polarization states. It can be seen that the detector is basically unchanged within 1000 s.

Response of Detector under Different Optical Powers:

the linear response of photodetector to different optical powers is a prerequisite for gray image processing. FIG. 5 shows the linear response of photocurrent to optical power under different polarization states, and the responsivity of the device can reach 800 mA/W at the maximum polarization state.

### Embodiment 2

The positive and negative photo-response detector in this embodiment is basically the same as that in embodiment 1, except that the bipolar two-dimensional semiconductor material is replaced by bipolar one-dimensional nanowires, and the performance is basically the same as that of the positive and negative photo-response detector in Embodiment 1 after testing.

The above description of the embodiments is intended to facilitate the understanding and use of the invention by those of ordinary skill in the art. Those skilled in the art will obviously easily make various modifications to these embodiments and apply the general principles described herein to other embodiments without creative effort. Accordingly, the present invention is not limited to the above-described embodiments, and improvements and modifications made by those skilled in the art according to the disclosure of the present invention without departing from the scope of the present invention should be within the scope of protection of the present invention.

1. A ferroelectric field modulated positive and negative photo-response detector, characterized in comprising a substrate (1), a gate electrode (2), a ferroelectric layer (3), a low-dimensional semiconductor (4) and a source-drain electrode (5);
wherein a pair of gate electrodes (2) are provided and fixedly arranged on the substrate (1) at intervals;
the ferroelectric layer (3) is fixedly arranged on the substrate (1) and completely covers the gate electrode (2);
the low-dimensional semiconductor (4) is fixedly arranged on the ferroelectric layer (3); and
the source-drain electrode (5) comprises a source electrode (51) and a drain electrode (52) separately arranged on two sides of the low-dimensional semiconductor (4) and fixedly arranged on the ferroelectric layer (3).

2. The ferroelectric field modulated positive and negative photo-response detector according to claim 1, characterized in that the substrate (1) is an insulating substrate.

3. The ferroelectric field modulated positive and negative photo-response detector according to claim 1, characterized in that the gate electrode (2) is a Cr/Au bottom gate electrode with a thickness of 10 nm/10 nm, and a distance between the two gate electrodes (2) is 1 μm.

4. The ferroelectric field modulated positive and negative photo-response detector according to claim 1, characterized in that the ferroelectric layer (3) contains a P (VDF-TrFE) ferroelectric material.

5. The ferroelectric field modulated positive and negative photo-photo-response detector according to claim 1, characterized in that the low-dimensional semiconductor (4) is aligned with the gate electrode (2).

6. The ferroelectric field modulated positive and negative photo-photo-response detector according to claim 1, characterized in that the source-drain electrode (5) is a Cr/Au source-drain electrode with a thickness of 15 nm/45 nm and a channel width of 10 μm.

7. A method of preparing the ferroelectric field modulated positive and negative photo-photo-response detector according to claim 1, characterized in comprising:
preparing a pair of gate electrodes (2) at intervals on a substrate (1) by a photolithography process, and preparing a ferroelectric layer (3) on the substrate (1) by a spin coating and annealing; preparing a low-dimensional semiconductor (4) on the ferroelectric layer (3) by a semiconductor transfer technique, then preparing an electrode pattern by an ultraviolet lithography method, preparing a source-drain electrode (5) by a thermal evaporation technique, and peeling off a metal film by a lift-off method to obtain the positive and negative photo-response detector.

8. The method of preparing the ferroelectric field modulated positive and negative photo-response detector according to claim 7, characterized in that the annealing is performed at 135° C. for 2 hours.

9. An application of the ferroelectric field modulated positive and negative photo-response detector according to claim 1 in an intelligent vision system.

10. The application of the ferroelectric field modulated positive and negative photo-response detector according to claim 9, characterized in that the positive and negative photo-response detector serves in an intelligent vision system as photoreceptor cells, bipolar cells and synapses connected to cerebral cortex of retina of human eyes.
